(19) United States
(12) Patent Application Publication
(10) Pub. No.: US 2022/0059316 A1
(43) Pub. Date: Feb. 24, 2022

(54) Scanning Electron Microscope Image Anchoring to Design for Array

(71) Applicant: KLA CORPORATION, Milpitas, CA (US)

(72) Inventors: Santosh Bhattacharyya, San Jose, CA (US); Steve Esbenshade, San Jose, CA (US)

(21) Appl. No.: 17/182,192

(22) Filed: Feb. 22, 2021

Related U.S. Application Data
(60) Provisional application No. 63/067,824, filed on Aug. 19, 2020.

(51) Int. Cl. H01J 37/28; H01J 37/244; G06T 7/00

(52) U.S. Cl. CPC H01J 37/28; H01J 37/244; G06T 7/0004; G06T 2207/10061; H01J 2237/2007; G06T 2207/30148; H01J 2237/2817

(57) ABSTRACT

A scanning electron microscope receives a results file for a wafer from an optical inspection system. The results file includes an anchor point on the wafer. A defect review image at the anchor point on the wafer is generated using the scanning electron microscope. A design clip is aligned to the defect review image at the anchor point thereby generating an aligned defect review image. The aligned defect review image is used for defect detection.

### CROSS-REFERENCE TO RELATED APPLICATIONS

This application claims priority to the provisional patent application filed Aug. 19, 2020 and assigned U.S. App. No. 63/067,824, the disclosure of which is hereby incorporated by reference.

### FIELD OF THE DISCLOSURE

The disclosure generally relates to semiconductor defect review.

### BACKGROUND OF THE DISCLOSURE

Evolution of the semiconductor manufacturing industry is placing greater demands on yield management and, in particular, on metrology and inspection systems. Critical dimensions continue to shrink, yet the industry needs to decrease time for achieving high-yield, high-value production. Minimizing the total time from detecting a yield problem to fixing it determines the return-on-investment for a semiconductor manufacturer.

Fabricating semiconductor devices, such as logic and memory devices, typically includes processing a semiconductor wafer using a large number of fabrication processes to form various features and multiple levels of the semiconductor devices. For example, lithography is a semiconductor fabrication process that involves transferring a pattern from a reticle to a photoresist arranged on a semiconductor wafer. Additional examples of semiconductor fabrication processes include, but are not limited to, chemical-mechanical polishing (CMP), etch, deposition, and ion implantation. Multiple semiconductor devices may be fabricated in an arrangement on a single semiconductor wafer that are separated into individual semiconductor devices.

Inspection processes are used at various steps during semiconductor manufacturing to detect defects on wafers to promote higher yield in the manufacturing process and, thus, higher profits. Inspection has always been an important part of fabricating semiconductor devices such as integrated circuits (ICs). However, as the dimensions of semiconductor devices decrease, inspection becomes even more important to the successful manufacture of acceptable semiconductor devices because smaller defects can cause the devices to fail. For instance, as the dimensions of semiconductor devices decrease, detection of defects of decreasing size has become necessary because even relatively small defects may cause unwanted aberrations in the semiconductor devices.

As design rules shrink, however, semiconductor manufacturing processes may be operating closer to the limitation on the performance capability of the processes. In addition, smaller defects can have an impact on the electrical parameters of the device as the design rules shrink, which drives more sensitive inspections. As design rules shrink, the population of potentially yield-relevant defects detected by inspection grows dramatically, and the population of nuisance defects detected by inspection also increases dramatically. Therefore, more defects may be detected on the wafers, and correcting the processes to eliminate all of the defects may be difficult and expensive. Determining which of the defects actually have an effect on the electrical parameters of the devices and the yield may allow process control methods to be focused on those defects while largely ignoring others. Furthermore, at smaller design rules, process-induced failures, in some cases, tend to be systematic. That is, process-induced failures tend to fail at predetermined design patterns often repeated many times within the design. Elimination of spatially-systematic, electrically-relevant defects can have an impact on yield.

Due to repeating pattern (i.e., cells) in an array area, a scanning electron microscope (SEM) tool often fails to align images to a design at a target location. Alignment often locks on to the incorrect repeating pattern, which results in a report with incorrect coordinates for the defect. Cell size needs to be larger than combined uncertainty in an optical inspection system (e.g., a broad band plasma (BBP) tool) and a stage in a scanning electron microscope (SEM). For example, the cell size may need to be larger than the (250 nm+125 nm)×2=750 nm for alignment to be successful at target location. In this example, 250 nm is for SEM and 125 nm is for the optical inspection system, but these values can change depending on the particular system. This value is multiplied by two because the value can be in either the positive or negative direction, so the cell size accounts for that. Often the cell size is smaller than this uncertainty.

Current techniques rely on a semiconductor manufacturer to provide design anchor locations. An SEM tool obtains a list of design anchor locations from the semiconductor manufacturer and for every defect target it finds the nearest anchor location. It moves the stage to the anchor location, grabs an image and design, performs alignment to design, and then moves to the target location adjusted by the alignment correction found at the anchor site. However, the SEM tool does not have an automated way of analyzing design to determine anchor locations. The semiconductor manufacturer may not provide anchor locations for all layers in the semiconductor device. The semiconductor manufacturer's anchor locations also may require different design layers compared to a target location design layer used for detection.

Thus, improved systems and techniques for semiconductor defect review are needed.

### SUMMARY OF THE DISCLOSURE

A method is provided in a first embodiment. The method includes receiving, at a scanning electron microscope tool, a results file for a wafer from an optical inspection system. The results file includes an anchor point on the wafer. A defect review image is generated at the anchor point on the wafer using the SEM. A design clip is aligned to the defect review image at the anchor point thereby generating an aligned defect review image. A defect is detected in the aligned defect review image.

The method can include determining the anchor point using the optical inspection system. The optical inspection system can generate pixel-to-design alignment image patches and the anchor point is selected from the pixel-to-design alignment image patches. The anchor point can be selected from the pixel-to-design alignment image patches using a generative adversarial network (GAN). Determining the anchor point can include ranking the pixel-to-design alignment image patches and selecting one of the pixel-to-design alignment image patches as the anchor point.

The design clip can be a 1 mm by 1 mm area on a die on the wafer.

The method can include performing a fine alignment of the defect review image using a target on the defect review image.

The aligned defect review image can have a location uncertainty of ±25 nm.

The detecting can occur during array mode.

A system is provided in a second embodiment. The system includes an SEM tool that includes a stage configured to hold a wafer; an electron beam source configured to emit electrons toward the wafer; and a detector configured to detect electrons received from the wafer. The system also includes a processor in electronic communication with the SEM configured to receive a results file from for a wafer from an optical inspection system. The results file includes an anchor point on the wafer. The processor is further configured to generate a defect review image at the anchor point on the wafer, align a design clip to the defect review image at the anchor point thereby generating an aligned defect review image, and detecting a defect in the aligned defect review image.

The system can include the optical inspection system. The optical inspection system can be configured to generate pixel-to-design alignment image patches and the anchor point can be selected from the pixel-to-design alignment image patches.

The system can include a GAN unit configured to select the anchor point from the pixel-to-design alignment image patches.

The design clip can be a 1 mm by 1 mm area on a die on the wafer.

The processor can be further configured to perform a fine alignment of the defect review image using a target on the defect review image.

The aligned defect review image can have a location uncertainty of ±25 nm.

A non-transitory, computer-readable storage medium is provided in a third embodiment. The non-transitory, computer-readable storage medium contains one or more programs configured to execute the following steps on one or more processors. The steps include receiving a results file from for a wafer from an optical inspection system. The results file includes an anchor point on the wafer. The steps also include generating a defect review image at the anchor point on the wafer, aligning a design clip to the defect review image at the anchor point thereby generating an aligned defect review image, and detecting a defect in the aligned defect review image.

The optical inspection system can be configured to generate pixel-to-design alignment image patches and the anchor point can be selected from the pixel-to-design alignment image patches.

The anchor point can be selected from the pixel-to-design alignment image patches using a GAN.

The anchor point can be received by the SEM from the optical inspection system via a results file.

The one or more programs can be further configured to perform a fine alignment of the defect review image using a target on the defect review image.

The aligned defect review image can have a location uncertainty of ±25 nm.

### BRIEF DESCRIPTION OF THE FIGURES

For a fuller understanding of the nature and objects of the disclosure, reference should be made to the following detailed description taken in conjunction with the accompanying drawings, in which:

FIG. 1 is a flowchart of a method in accordance with the present disclosure; and

FIG. 2 is a block diagram of a system in accordance with the present disclosure.

### DETAILED DESCRIPTION OF THE DISCLOSURE

Although claimed subject matter will be described in terms of certain embodiments, other embodiments, including embodiments that do not provide all of the benefits and features set forth herein, are also within the scope of this disclosure. Various structural, logical, process step, and electronic changes may be made without departing from the scope of the disclosure. Accordingly, the scope of the disclosure is defined only by reference to the appended claims.

Using embodiments disclosed herein, an SEM image is aligned to a design at a nearby location to a target and then the stage is moved to a target location for defect detection. Pixel-to-design alignment (PDA) targets can be reused to obtain anchor locations for all array targets. If an anchor site is 1-2 mm away from a target site, stage inaccuracy of ±125 nm can be reduced to approximately ±25 nm.

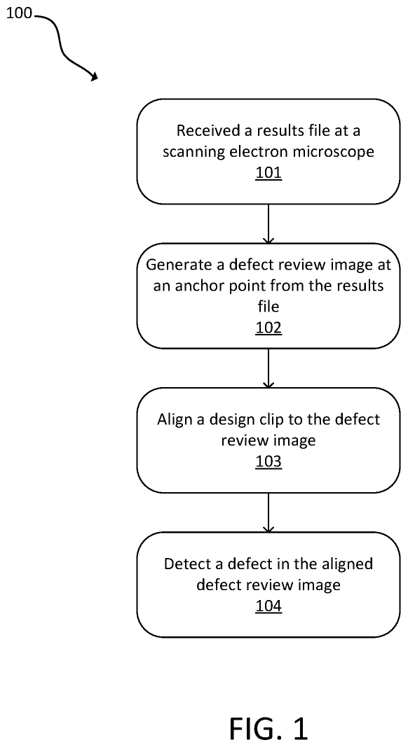

FIG. 1 is a flowchart of a method 100. At 101, an SEM tool receives a results file for a wafer from an optical inspection system, such as a BBP inspection system. The results file includes an anchor point on the wafer. In an example, the results file is a KLARF file used by KLA Corporation, which may include defect locations, features extracted from the images acquired at these locations, image patches, defect classification, or other information.

An anchor location can be added to the results file per (array) defect location. These defect locations can be added as new defect locations, but the defect locations may have their own rough bin code to identify them as anchor points. While disclosed with respect to an array, the anchor location can be used in random designs where there is sparse geometry around the defect location such that the alignment will not work at the defect site.

The anchor point can be determined using the optical inspection system. For example, the optical inspection system can generate pixel-to-design alignment image patches. The optical inspection system can perform pixel-to-design alignment and can save the image patches and design clips.

The anchor point is selected from the pixel-to-design alignment image patches. In an instance, the anchor point is selected from the pixel-to-design alignment image patches using a GAN. Determining the anchor point can include ranking the pixel-to-design alignment image patches and selecting one of the pixel-to-design alignment image patches as the anchor point. The GAN can be trained on a sampling of representative patterns using the design clip and corresponding optical and SEM images. Ranking can be based on alignment quality and uniqueness metrics for the image patches. Better alignment quality and uniqueness may be selected.

Thus, the optical inspection system can render a design clip at every pixel-to-design location or sub-selected locations. The optical inspection system can determine if the location is suitable for SEM alignment, which may be similar to the ranking based on image quality and uniqueness metrics. If a trained GAN network for this layer is available, an SEM look-alike image can be generated for further analysis of alignment suitability. An SEM look-alike image can be generated using a GAN using a design file as an input.

In an example, the optical inspection system can perform a process, which may be an offline process, that renders one or more design clips as black and white images at the SEM image scale (e.g., 2 nm pixel size). The optical inspection system can determine if the location is a suitable alignment target. Aspects of the rendered image such as pattern repetition, image contrast, noise, or other aspects can be considered to determine if the location is acceptable for SEM alignment. A suitability matrix per target can be generated. Graphical design system (GDS) locations of selected targets can be saved as part of the recipe for the optical inspection tool. GDS is a format that can be used to store a semiconductor device design.

In an instance, one target is selected per a 1 μm by 1 μm grid. For a 30 mm by 30 mm die, this results in 900 GDS locations. The GAN or design rendering can be used to perform sub-selection of the GDS locations. The pixel-to-design alignment locations can be stored. During runtime, the pixel-to-design alignment locations nearest to each defect can be added to the locations to grab review images.

The optical inspection system also can add anchor points to the results file.

The optical inspection system can adjust a target location in a target image frame given alignment correction found at an anchor point. There may be a shift in the X direction and perpendicular Y direction based on the alignment correction.

The optical inspection system also can apply a location filter to reduce nuisance. Care areas defined based on a design can be applied using the accurate defect coordinates. The location filter can be a care area, which can be defined in the GDS to avoid certain structures.

At 102, a defect review image is generated at the anchor point on the wafer using the SEM.

At 103, a design clip is aligned to the defect review image at the anchor point using the GAN. This generates an aligned defect review image. For example, the design clip may be a 1 mm by 1 mm area on a die on the wafer and may be the review image size. Of course, the design clip may be other sizes. Fine alignment of the defect review image can be performed using a target on the defect review image. Coarse alignment can be performed on the anchor location image, which may not be in a repeating area. Fine alignment can be performed on the defect location image and may not align to a neighboring cell. For example, a design clip in input to generate an SEM look-alike image that is used for alignment.

In an instance, the stage that holds the wafer can be moved to a target location for defect detection.

The aligned defect review image can have a location uncertainty of ±25 nm. This is the expected accuracy given the residual errors in the alignment. Accurate defect localization can be important to obtain accurate defect classification based on the high-resolution SEM image to make sure the correct pixels from the SEM image are used in the classification. Different location uncertainties can be provided, which may be used with particular applications. A location uncertainty of ±25 nm provides improvements over previous systems.

A defect is detected in the aligned defect review image at 104. This can be a coordinate correction of the defect location(s) found in the review image. Accurate overlay of the defects found in the SEM review and BBP optical images can be provided. Resolution of an SEM tool can be used to classify a defect. For example, defect detection can occur during array mode defect detection. Coarse design-to-SEM alignment can be performed at a nearest anchor point. Fine alignment can be performed at the target location. This can be helpful if there are two defects in a single field of view because without alignment it the wrong defect may be classified or a search may be performed at the wrong location.

SEM images for all results file locations can be collected to the optical inspection system workstation.

Fusion of optical inspection tool and SEM tool can enable design locations to be obtained from optical inspection tool during a pixel-to design-alignment setup step, which offers a throughput advantage over what an SEM tool can do by itself.

The results file can add an anchor point for each defect. One anchor point can be added for several defects if the defects are within a particular radius. The radius can be a function of cell size and accuracy of the SEM review tool. The accuracy of the SEM review tool also can be a function of the distance between the anchor point and the target location. The radius can be optimized if there is a cluster of defects.

For every defect corresponding to an anchor SEM image that is located, a design clip can be extracted. The design clip can be rendered (using images or a GAN) and the rendered clip can be aligned to the corresponding SEM image. A determined offset can be used to modify defect location of corresponding target defect. This will reduce the location uncertainty from previous ±125 nm to ±25 nm.

In an example, a die is divided into 1 mm by 1 mm grid (or some other predetermined grid unit) and one or more locations per grid can be selected as anchor points. The grid can be ranked. Thus, a predictable number of anchor locations are available and maximum allowed distance from target to anchor location can be satisfied. A location filter used during defect detection can be adjusted to be smaller after such anchor alignment is successful.

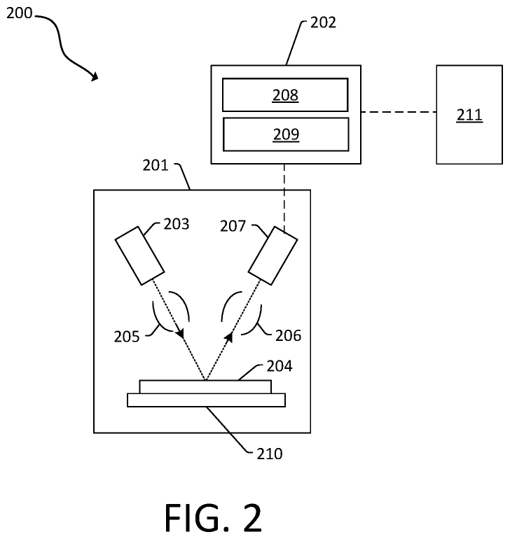

FIG. 2 is a block diagram of an embodiment of a system 200. The system 200 includes a wafer inspection tool (which includes the electron column 201) configured to generate images of a wafer 204.

The wafer inspection tool includes an output acquisition subsystem that includes at least an energy source and a detector. The output acquisition subsystem may be an electron beam-based output acquisition subsystem. For example, in one embodiment, the energy directed to the wafer 204 includes electrons, and the energy detected from the wafer 204 includes electrons. In this manner, the energy source may be an electron beam source. In one such embodiment shown in FIG. 2, the output acquisition subsystem includes electron column 201, which is coupled to computer subsystem 202. A stage 210 may hold the wafer 204.

As also shown in FIG. 2, the electron column 201 includes an electron beam source 203 configured to generate electrons that are focused to wafer 204 by one or more elements 205. The electron beam source 203 may include, for example, a cathode source or emitter tip. The one or more elements 205 may include, for example, a gun lens, an anode, a beam limiting aperture, a gate valve, a beam current selection aperture, an objective lens, and a scanning subsystem, all of which may include any such suitable elements known in the art.

Electrons returned from the wafer 204 (e.g., secondary electrons) may be focused by one or more elements 206 to detector 207. One or more elements 206 may include, for example, a scanning subsystem, which may be the same scanning subsystem included in element(s) 205.

The electron column 201 also may include any other suitable elements known in the art.

Although the electron column 201 is shown in FIG. 2 as being configured such that the electrons are directed to the wafer 204 at an oblique angle of incidence and are scattered from the wafer 204 at another oblique angle, the electron beam may be directed to and scattered from the wafer 204 at any suitable angles. In addition, the electron beam-based output acquisition subsystem may be configured to use multiple modes to generate images of the wafer 204 (e.g., with different illumination angles, collection angles, etc.). The multiple modes of the electron beam-based output acquisition subsystem may be different in any image generation parameters of the output acquisition subsystem.

Computer subsystem 202 may be coupled to detector 207 as described above. The detector 207 may detect electrons returned from the surface of the wafer 204 thereby forming electron beam images of the wafer 204. The electron beam images may include any suitable electron beam images. Computer subsystem 202 may be configured to perform any of the functions described herein using the output of the detector 207 and/or the electron beam images. Computer subsystem 202 may be configured to perform any additional step(s) described herein. A system 200 that includes the output acquisition subsystem shown in FIG. 2 may be further configured as described herein.

It is noted that FIG. 2 is provided herein to generally illustrate a configuration of an electron beam-based output acquisition subsystem that may be used in the embodiments described herein. The electron beam-based output acquisition subsystem configuration described herein may be altered to optimize the performance of the output acquisition subsystem as is normally performed when designing a commercial output acquisition system. In addition, the systems described herein may be implemented using an existing system (e.g., by adding functionality described herein to an existing system). For some such systems, the methods described herein may be provided as optional functionality of the system (e.g., in addition to other functionality of the system). Alternatively, the system described herein may be designed as a completely new system.

Although the output acquisition subsystem is described above as being an electron beam-based output acquisition subsystem, the output acquisition subsystem may be an ion beam-based output acquisition subsystem. Such an output acquisition subsystem may be configured as shown in FIG. 2 except that the electron beam source may be replaced with any suitable ion beam source known in the art. In addition, the output acquisition subsystem may be any other suitable ion beam-based output acquisition subsystem such as those included in commercially available focused ion beam (FIB) systems, helium ion microscopy (HIM) systems, and secondary ion mass spectroscopy (SIMS) systems.

The computer subsystem 202 includes a processor 208 and an electronic data storage unit 209. The processor 208 may include a microprocessor, a microcontroller, or other devices.

The computer subsystem 202 may be coupled to the components of the system 200 in any suitable manner (e.g., via one or more transmission media, which may include wired and/or wireless transmission media) such that the processor 208 can receive output. The processor 208 may be configured to perform a number of functions using the output. The wafer inspection tool can receive instructions or other information from the processor 208. The processor 208 and/or the electronic data storage unit 209 optionally may be in electronic communication with another wafer inspection tool, a wafer metrology tool, or a wafer review tool (not illustrated) to receive additional information or send instructions.

The processor 208 is in electronic communication with the wafer inspection tool, such as the detector 207. The processor 208 may be configured to process images generated using measurements from the detector 207. For example, the processor may perform embodiments of the method 100.

The computer subsystem 202, other system(s), or other subsystem(s) described herein may be part of various systems, including a personal computer system, image computer, mainframe computer system, workstation, network appliance, internet appliance, or other device. The subsystem(s) or system(s) may also include any suitable processor known in the art, such as a parallel processor. In addition, the subsystem(s) or system(s) may include a platform with high-speed processing and software, either as a standalone or a networked tool.

The processor 208 and electronic data storage unit 209 may be disposed in or otherwise part of the system 200 or another device. In an example, the processor 208 and electronic data storage unit 209 may be part of a standalone control unit or in a centralized quality control unit. Multiple processors 208 or electronic data storage units 209 may be used.

The processor 208 may be implemented in practice by any combination of hardware, software, and firmware. Also, its functions as described herein may be performed by one unit, or divided up among different components, each of which may be implemented in turn by any combination of hardware, software and firmware. Program code or instructions for the processor 208 to implement various methods and functions may be stored in readable storage media, such as a memory in the electronic data storage unit 209 or other memory.

If the system 200 includes more than one computer subsystem 202, then the different subsystems may be coupled to each other such that images, data, information, instructions, etc. can be sent between the subsystems. For example, one subsystem may be coupled to additional subsystem(s) by any suitable transmission media, which may include any suitable wired and/or wireless transmission media known in the art. Two or more of such subsystems may also be effectively coupled by a shared computer-readable storage medium (not shown).

The processor 208 may be configured to perform a number of functions using the output of the system 200 or other output. For instance, the processor 208 may be configured to send the output to an electronic data storage unit 209 or another storage medium. The processor 208 may be further configured as described herein.

In an example, the processor 208 is configured to receive a results from for a wafer from an optical inspection system, such as the optical inspection system 211. The results file includes an anchor point on the wafer. The processor 208 generates a defect review image at the anchor point on the wafer 204; aligns a design clip to the defect review image at the anchor point thereby generating an aligned defect review image; and detects a defect in the aligned defect review image. The design clip may be a 1 mm by 1 mm area on a die on the wafer 204. The aligned defect review image may have a location uncertainty of ±25 nm. A 1 mm by 1 mm area can be used based on the accuracy of the SEM review tool and the ability for image context around a defect so image processing algorithms can align and perform defect detection and classification. Smaller design clip sizes are possible and 1 mm by 1 mm is merely an example.

In this example, the optical inspection system 211 can be configured to pixel-to-design alignment image patches. The anchor point is selected from the pixel-to-design alignment image patches. A GAN unit in the computer subsystem 202 or optical inspection system 211 can be configured to select the anchor point from the pixel-to-design alignment image patches. The GAN unit can be or can be run by a processor, such as the processor 208.

The processor 208 can be further configured to perform a fine alignment of the defect review image using a target on the defect review image.

The processor 208 also can configured to align an SEM image to a design at a nearby location to a target. The processor 208 can send instructions to the stage 208 to move to a target location for defect detection.

The processor 208 or computer subsystem 202 may be part of a defect review system, an inspection system, a metrology system, or some other type of system. Thus, the embodiments disclosed herein describe some configurations that can be tailored in a number of manners for systems having different capabilities that are more or less suitable for different applications.

The processor 208 may be configured according to any of the embodiments described herein. The processor 208 also may be configured to perform other functions or additional steps using the output of the system 200 or using images or data from other sources.

The processor 208 may be communicatively coupled to any of the various components or sub-systems of system 200 in any manner known in the art. For example, the computer subsystem 202 can be coupled to an optical inspection system 211. Moreover, the processor 208 may be configured to receive and/or acquire data or information from other systems (e.g., inspection results from an inspection system such as a review tool, a remote database including design data and the like) by a transmission medium that may include wired and/or wireless portions. In this manner, the transmission medium may serve as a data link between the processor 208 and other subsystems of the system 200 or systems external to system 200.

Various steps, functions, and/or operations of system 200 and the methods disclosed herein are carried out by one or more of the following: electronic circuits, logic gates, multiplexers, programmable logic devices, ASICs, analog or digital controls/switches, microcontrollers, or computing systems. Program instructions implementing methods such as those described herein may be transmitted over or stored on carrier medium. The carrier medium may include a storage medium such as a read-only memory, a random access memory, a magnetic or optical disk, a non-volatile memory, a solid state memory, a magnetic tape, and the like. A carrier medium may include a transmission medium such as a wire, cable, or wireless transmission link. For instance, the various steps described throughout the present disclosure may be carried out by a single processor 208 (or computer subsystem 202) or, alternatively, multiple processors 208 (or multiple computer subsystems 202). Moreover, different sub-systems of the system 200 may include one or more computing or logic systems. Therefore, the above description should not be interpreted as a limitation on the present disclosure but merely an illustration.

In an instance, a non-transitory, computer-readable storage medium containing one or more programs is provided. The one or more programs are configured to execute the following steps on one or more processors. First, results are received from for a wafer from an optical inspection system. The results file includes an anchor point on the wafer. Second, a defect review image is generated at the anchor point on the wafer. Third, a design clip is aligned to the defect review image at the anchor point thereby generating an aligned defect review image.

Fourth, a defect in the aligned defect review image is detected. The aligned defect review image can have a location uncertainty of ±25 nm.

The optical inspection system can be configured to generate pixel-to-design alignment image patches and the anchor point can be selected from the pixel-to-design alignment image patches. In an instance, the anchor point is selected from the pixel-to-design alignment image patches using a GAN.

The anchor point can be received by the SEM from the optical inspection system via a results file.

The one or more programs can be further configured to perform a fine alignment of the defect review image using a target on the defect review image.

The steps of the method described in the various embodiments and examples disclosed herein are sufficient to carry out the methods of the present invention. Thus, in an embodiment, the method consists essentially of a combination of the steps of the methods disclosed herein. In another embodiment, the method consists of such steps.

Each of the steps of the method may be performed as described herein. The methods also may include any other step(s) that can be performed by the processor and/or computer subsystem(s) or system(s) described herein. The steps can be performed by one or more computer systems, which may be configured according to any of the embodiments described herein. In addition, the methods described above may be performed by any of the system embodiments described herein.

Although the present disclosure has been described with respect to one or more particular embodiments, it will be understood that other embodiments of the present disclosure may be made without departing from the scope of the present disclosure.

What is claimed is:

1. A method, comprising:
receiving, at a scanning electron microscope tool, a results file for a wafer from an optical inspection system, wherein the results file includes an anchor point on the wafer;
generating a defect review image at the anchor point on the wafer using the scanning electron microscope;
aligning a design clip to the defect review image at the anchor point thereby generating an aligned defect review image; and
detecting a defect in the aligned defect review image.

2. The method of claim 1, further comprising determining the anchor point using the optical inspection system, wherein the optical inspection system generates pixel-to-design alignment image patches and the anchor point is selected from the pixel-to-design alignment image patches.

3. The method of claim 2, wherein the anchor point is selected from the pixel-to-design alignment image patches using a generative adversarial network.

4. The method of claim 2, wherein determining the anchor point includes ranking the pixel-to-design alignment image patches and selecting one of the pixel-to-design alignment image patches as the anchor point.

5. The method of claim 1, wherein the design clip is a 1 mm by 1 mm area on a die on the wafer.

6. The method of claim 1, further comprising performing a fine alignment of the defect review image using a target on the defect review image.

7. The method of claim 1, wherein the aligned defect review image has a location uncertainty of ±25 nm.

8. The method of claim 1, wherein the detecting occurs during array mode.

9. A system, comprising:
a scanning electron microscope tool, including:
a stage configured to hold a wafer;
an electron beam source configured to emit electrons toward the wafer; and
a detector configured to detect electrons received from the wafer;
a processor in electronic communication with the scanning electron microscope, configured to:
receive a results file from for a wafer from an optical inspection system, wherein the results file includes an anchor point on the wafer;
generate a defect review image at the anchor point on the wafer;
align a design clip to the defect review image at the anchor point thereby generating an aligned defect review image; and
detecting a defect in the aligned defect review image.

10. The system of claim 9, further comprising the optical inspection system, wherein the optical inspection system is configured to generate pixel-to-design alignment image patches and the anchor point is selected from the pixel-to-design alignment image patches.

11. The system of claim 10, further comprising a generative adversarial network unit configured to select the anchor point from the pixel-to-design alignment image patches.

12. The system of claim 9, wherein the design clip is a 1 mm by 1 mm area on a die on the wafer.

13. The system of claim 9, wherein the processor is further configured to perform a fine alignment of the defect review image using a target on the defect review image.

14. The system of claim 9, wherein the aligned defect review image has a location uncertainty of ±25 nm.

15. A non-transitory, computer-readable storage medium containing one or more programs configured to execute the following steps on one or more processors:
receive a results file from for a wafer from an optical inspection system, wherein the results file includes an anchor point on the wafer;
generate a defect review image at the anchor point on the wafer;
align a design clip to the defect review image at the anchor point thereby generating an aligned defect review image; and
detect a defect in the aligned defect review image.

16. The non-transitory, computer-readable storage medium of claim 15, wherein the optical inspection system is configured to generate pixel-to-design alignment image patches and the anchor point is selected from the pixel-to-design alignment image patches.

17. The non-transitory, computer-readable storage medium of claim 16, wherein the anchor point is selected from the pixel-to-design alignment image patches using a generative adversarial network.

18. The non-transitory, computer-readable storage medium of claim 15, wherein the anchor point is received by the scanning electron microscope from the optical inspection system via a results file.

19. The non-transitory, computer-readable storage medium of claim 15, wherein the one or more programs are further configured to perform a fine alignment of the defect review image using a target on the defect review image.

20. The non-transitory, computer-readable storage medium of claim 15, wherein the aligned defect review image has a location uncertainty of ±25 nm.
